(19) United States
(12) Patent Application Publication
(10) Pub. No.: US 2025/0347539 A1
(43) Pub. Date: Nov. 13, 2025

(54) POSITION MEASURING DEVICE

(71) Applicant: DR. JOHANNES HEIDENHAIN GmbH, Traunreut (DE)

(72) Inventors: Udo Ollert, Kirchweidach (DE); Johannes Hilverkus, Marquartstein (DE); Johannes Schneider, Traunstein (DE)

(21) Appl. No.: 19/194,034

(22) Filed: Apr. 30, 2025

(30) Foreign Application Priority Data
May 7, 2024 (DE) 10 2024 001 488.8

(51) Int. Cl. G01D 11/24; G01D 5/14; H05K 1/18

(52) U.S. Cl. CPC G01D 11/245; G01D 5/145; H05K 1/18

(57) ABSTRACT

A position measuring device including a first component group and a second component group. The component groups are arranged so as to be movable relative to one another in a measurement direction. The first component group includes a first printed circuit board, which includes a detector and a second printed circuit board, which includes a domain-wall conductor. The first printed circuit board is arranged offset from the second printed circuit board in the measurement direction. The second component group includes a scale and a magnet. The scale is arranged between the magnet and the second printed circuit board. The scale is configured to be read by the detector to determine a relative position in the measurement direction. The magnet is configured and arranged such that the magnet generates a displacement of a domain wall in the domain-wall conductor when the magnet travels past domain-wall conductor.

### CROSS REFERENCE TO RELATED APPLICATIONS

This application claims benefit to German Patent Application No. DE 10 2024 001 488.8, filed on May 7, 2024, which is hereby incorporated by reference herein.

### FIELD

The invention relates to a position measuring.

### BACKGROUND

Angular-position measuring devices are used, for example, as rotary encoders for determining the angular position of two machine parts that are rotatable relative to one another. Often, what are known as multi-turn angular-position measuring devices are used for this purpose, which allow for absolute position determination over several revolutions.

In addition, linear measuring devices are known, in which a linear displacement of two machine parts that are displaceable relative to one another is measured. Particularly in linear measuring devices that have a relatively large measurement length, a plurality of linear or identical scales are often mounted end to end in the measurement direction. In these linear measuring devices, absolute position determination should ideally be possible over the entire measurement length.

Often, these measuring devices or measuring instruments are used for electrical drives to determine the relative movement or relative position of relevant machine parts. In this case, the position values generated are supplied to subsequent electronics for actuating the drives by way of a corresponding interface arrangement.

For many applications of position measuring devices, particularly angular-position measuring devices or linear measuring devices, it is important to store at least numbers of revolutions or rough positions in a non-volatile manner.

EP 4 170 289 A1 belonging to the applicant describes a position measuring device for measuring an angular position, based on an inductive measurement principle.

In addition, document EP 3 387 387 B1 discloses a magnetic revolution counter comprising a domain-wall memory.

### SUMMARY

In an embodiment, the present disclosure provides a position measuring device comprising a first component group and a second component group. The component groups are arranged so as to be movable relative to one another in a measurement direction. The first component group comprises a first printed circuit board, which comprises a detector and a second printed circuit board, which comprises a domain-wall conductor. The first printed circuit board is arranged offset from the second printed circuit board in the measurement direction. The second component group comprises a scale and a magnet. The scale is arranged between the magnet and the second printed circuit board. The scale is configured to be read by the detector to determine a relative position in the measurement direction. The magnet is configured and arranged such that the magnet generates a displacement of a domain wall in the domain-wall conductor when the magnet travels past domain-wall conductor.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates a perspective exploded view of a position measuring device according to an embodiment example;

FIG. 2 illustrates a plan view of a first component group of a position measuring device;

FIG. 3 illustrates a plan view of a second component group of the position measuring device;

FIG. 4 illustrates a plan view of two magnets of the second component group;

FIG. 5 illustrates a plan view of a domain-wall conductor;

FIG. 6 illustrates a sectional view of a detail of the position measuring device; and

FIG. 7 illustrates a sectional view of a detail of the position measuring device according to an embodiment example.

### DETAILED DESCRIPTION

In an embodiment, the present disclosure provides a position measuring device that comprises a domain-wall memory and has a relatively simple, compact construction and operates with precision. The domain-wall memory can be configured for storing revolution or position information, for example for an angular-position measuring device or a linear measuring device.

According to an embodiment, the position measuring device comprises a first component group and a second component group, the component groups being arranged so as to be movable relative to one another in a measurement direction. The first component group has a first printed circuit board, which comprises a detector unit. In addition, the first component group has a second printed circuit board, which comprises a domain-wall conductor. The first printed circuit board is arranged in a manner offset from the second printed circuit board in the measurement direction. The second component group comprises a scale and at least one magnet. The scale is arranged between the magnet and the second printed circuit board. In order to determine the relative position between the scale and the detector unit in the measurement direction, the detector unit can read the scale. The at least one magnet is configured and arranged such that it can generate a displacement of at least one domain wall in the domain-wall conductor when the magnet travels past it.

A domain-wall conductor consists of a magnetizable material and, in the context of the present disclosure, is configured in particular as at least one conducting trace or conducting track or a nanowire. The domain-wall conductor runs on a substrate. In the domain-wall conductor, information can be stored in the form of regions (domains) of opposite magnetization. The domains are separated along the conducting trace by what are known as domain walls, which can be displaced by magnetic fields, with the positions of the domains changing in the process. A domain-wall conductor of this kind can be encased by a housing comprising electronic connection sites such as pins, leads, or balls. The housing is used to fasten the domain-wall memory to the second printed circuit board.

By way of example, the scale can be applied to a first side of a substrate, and the at least one magnet can be arranged on the opposite side of the substrate. Alternatively, the scale can be applied to the at least one magnet such that the magnet serves as a load-bearing substrate, thereby reducing the number of required parts in the second component group.

Advantageously, the domain-wall conductor is arranged in a housing which is mounted on a first surface of the second printed circuit board. A first distance between the scale and the detector unit is of a first length. A second distance between the first surface and the scale is of a second length. The first length is less than the second length or at least equal to the second length. The first and the second distance, or the first and the second length, extend in a third direction oriented orthogonally to the measurement direction.

If the scale or the detector unit is intended to be configured such as to extend along the direction of the first distance, then the first length is the shortest length.

In an embodiment of the present disclosure, a third distance extending between the domain-wall conductor and the scale is of a third length. The first length of the first distance between the scale and the detector unit is less than the third length or at least equal to the third length.

A domain-wall memory comprises an in particular planar substrate, and the domain-wall conductor is configured as a conducting track on the substrate. In this case, the face in which the domain-wall conductor runs is planar. Alternatively, the face could also be configured in a curved manner, in particular if the domain-wall conductor is opposite magnets that have a curved surface.

The structural width of the domain-wall conductor is usually less than 500 nm, often less than 300 nm, and the thickness or layer thickness of the domain-wall conductor is less than 60 nm. The domain-wall memory can comprise a plurality of domain-wall conductors.

The domain-wall memory furthermore has readout elements by which the local magnetization status of the domain-wall conductor (at the position of each readout element) can be determined. A magnetization status of each domain-wall conductor can therefore be determined by the readout elements. The readout elements are arranged in a fixed manner with respect to the domain-wall conductor. GMR or TMR sensors are possible readout elements, for example. A domain-wall memory thus comprises the domain-wall conductor(s), the substrate, readout elements, and the housing.

According to an embodiment of the present disclosure, the first printed circuit board and the second printed circuit board are each configured in multiple layers such that they comprise a plurality of electrically conductive layers. In this case, the layered construction of the first printed circuit board can differ from the layered construction of the second printed circuit board. The first printed circuit board and the second printed circuit board can in particular have different numbers of layers. For example, the thicknesses of the electrically conductive layers of the first printed circuit board can also differ from the thicknesses of the layers of the second printed circuit board. Furthermore, the first and the second printed circuit board can be made of different materials, for example. Moreover, one of the printed circuit boards can have components fitted on one side, and the other printed circuit board can have components fitted on both sides. In particular, the first and the second printed circuit board can be arranged with respect to one another such as to have surfaces that run in different geometric planes, the printed circuit boards in particular being arranged in a manner offset from one another.

Advantageously, the position measuring device is configured such that its operating principle is based on an inductive measurement principle, the detector unit then having at least one receiver conducting track.

Alternatively or additionally, a magnetic or optical operating principle can be used. In the latter case, the detector unit on the first printed circuit board can comprise a photodiode or a photodiode array. A light source, for example an LED, can also then be mounted on the first printed circuit board. In the case of incident-light reading, the scale would then consist of reflective scale regions and non-reflective scale regions. Alternatively, a transmitted-light method could also be used, in which the scale consists of opaque and transparent scale regions, and the light source is then not mounted on the first printed circuit board.

Advantageously, the position measuring device is configured as an angular-position measuring device such that the measurement direction corresponds to a circumferential direction.

In an embodiment of the present disclosure, the first printed circuit board is configured in the manner of a ring segment, in particular in a horseshoe shape, and extends in the measurement direction over an angle of at least 180°, in particular over an angle of at least 200°, in particular over an angle of at least 270°.

The second printed circuit board can then also be configured in the manner of a ring segment. The second printed circuit board extends in the measurement direction over an angle of less than 180°, in particular over an angle of less than 120°, in particular over an angle of less than 90°.

Advantageously, the material of the at least one magnet comprises plastics material having a magnetizable filler. In particular, at least one of the magnets can be produced by a pressing method or an injection molding method.

Advantageously, the first component group and the second component group are arranged so as to be rotatable relative to one another about an axis, and the axis does not intersect or pass through the face in which the domain-wall conductor runs.

The domain-wall conductor is thus radially offset from the axis; this configuration is often also referred to as an off-axis arrangement.

In an embodiment of the present disclosure, the second component group comprises at least two magnets mounted end to end in the measurement direction. Advantageously, the second component group comprises two magnets which are configured to be identical.

Advantageously, the magnets mounted end to end in the measurement direction are magnetized such that their magnetization directions run with an orthogonal directional component with respect to the face in which the domain-wall conductor runs. In addition, the magnets are arranged such that they have opposite magnetization directions. Moreover, the magnets are arranged and configured such that the distance in the measurement direction between the first magnet and the second magnet varies in size along a second direction that is oriented orthogonally to the measurement direction. The face in which the domain-wall conductor runs extends both along the measurement direction and along the second direction. The normal vector of the face is oriented in the third direction. In other words, the measurement direction is oriented orthogonally to the second direction and orthogonally to the third direction.

Between the first magnet and the second magnet there is thus a gap which extends in the measurement direction and the length of which in the measurement direction varies in size along the second direction. The contours, facing one another in the measurement direction, of the ends of the magnets are in particular configured such that they diverge at least over a region extending in the second direction.

Advantageously, the magnets are arranged end to end in the measurement direction in such a way that they do not touch. Consequently, the minimum distance between the first magnet and the second magnet in the measurement direction is greater than zero.

Since there is a distance between the first and the second magnet in the measurement direction, there is an interstice in this region which either consists of air or is filled with largely non-magnetic material.

The magnetization direction can be understood as the direction of a connecting line between the north pole and the south pole of a magnet. The magnets are preferably magnetized through their thickness.

In an embodiment of the present disclosure, at least one of the magnets is configured such that it has an asymmetric form with respect to a line running in parallel with the measurement direction and orthogonally to the magnetization direction. This asymmetry can be obtained in particular by configuring at least one end of one magnet to be asymmetric.

Advantageously, at least one of the magnets is configured at its end such that the contour thereof runs in a curved manner.

In the case of a position measuring device configured as an angular-position measuring device, the second direction runs either in the radial direction or in the axial direction (drum arrangement), and the measurement direction corresponds to the circumferential or tangential direction. In this configuration too, the second direction is always oriented orthogonally to the measurement direction. In addition, the second direction runs orthogonally to the magnetization direction.

The geometric considerations described here apply to the spatial region in which the relevant magnet is opposite the domain-wall conductor, “from the perspective” of the domain-wall conductor, as it were. For example, starting from the domain-wall conductor, the magnetization directions run orthogonally to the face of the domain-wall conductor even when the magnets are rotating.

Between the domain-wall conductor and the magnets there is a fourth distance of a fourth length. The fourth length or the fourth distance extends orthogonally to the face in which the domain-wall conductor runs (i.e., in the third direction), the minimum distance in the measurement direction between the magnets being less than half the fourth length. In the event that the fourth length is not intended to be the same over the entire face of the domain-wall conductor, then in particular the minimum distance between the magnets is less than half the smallest fourth length.

Advantageously, in relation to the second direction, the domain-wall conductor is positioned such that the magnets pass by it in the region of a distance between the magnets that is less than the maximum distance. When the magnets travel past the domain-wall conductor, the domain-wall conductor is located in the region of the relatively small distance between the magnets and is influenced by the magnetic field lines prevailing there. In particular, in relation to the second direction, the domain-wall conductor is positioned such that the magnets pass by it in the region of the smallest distance. When the magnets travel past the domain-wall conductor, the domain-wall conductor is then located in the region of the smallest distance between the magnets and is influenced by the magnetic field lines prevailing there.

The position measuring device can be used as an angular-position measuring device in which numbers of revolutions in particular are stored. Alternatively, the position measuring device can be configured as a linear measuring instrument having a linear scale for measuring linear displacements. The scale can in particular comprise a first scale part and a second scale part. The first scale part and the second scale part can, for example, be arranged end to end along the measurement direction such that a relatively large measurement length can be obtained. In practice, of course, more than just two scale parts can be arranged end to end. Magnets are then provided in a manner offset from one another along the first direction. Using the domain-wall memory, corresponding position information can be stored so that it can be established which of the scale parts is currently being read.

Further details and advantages of the position measuring device according to the present disclosure will become apparent from the following description of embodiment examples with reference to the accompanying drawings.

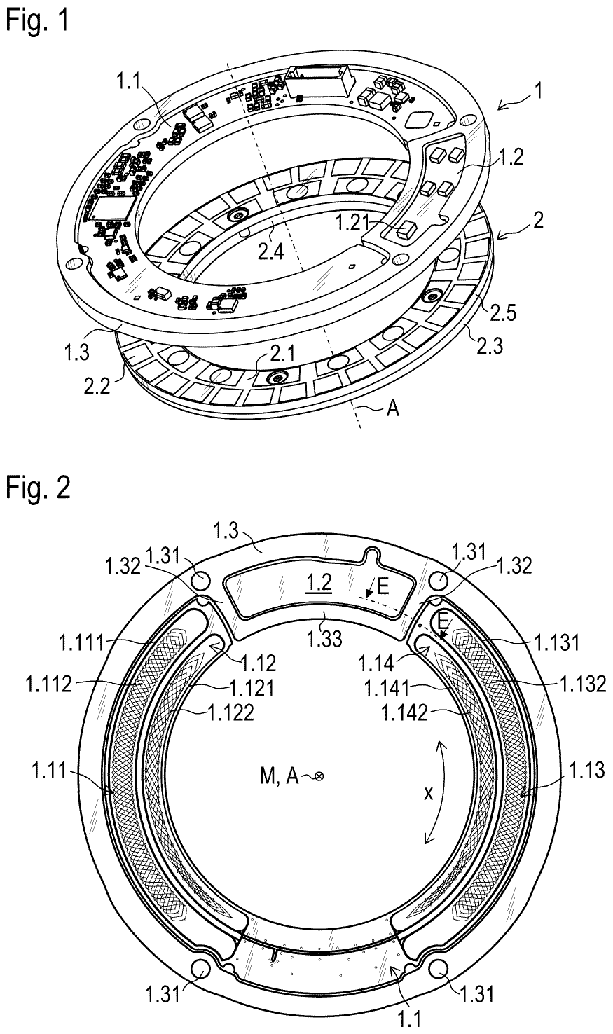

FIG. 1 shows a position measuring device that comprises a first component group 1 and a second component group 2, the component groups 1, 2 being arranged so as to be rotatable relative to one another about an axis A. A position measuring device of this kind is used as an angular-position measuring device. FIG. 1 is a perspective exploded view, so the distance between the first component group 1 and the second component group 2 is greater than during actual operation of the position measuring device.

The first component group 1 comprises a first printed circuit board 1.1, which has a plurality of layers, and electronic components. The first component group 1 also comprises a frame 1.3 as a mechanically load-bearing structure.

As also shown in FIG. 2, the first printed circuit board 1.1 is in the form of a circular ring segment that is configured to extend around more than approximately 300° and accordingly has an opening. The closed, substantially annular frame 1.3 (made of metal here) is fastened around the outside of the first printed circuit board 1.1 and in particular is used for mechanically reinforcing the first component group 1 and has fastening regions 1.31, in this case in the form of holes. In the region of the opening in the first printed circuit board 1.1, ribs 1.32 of the frame 1.3 run in parallel with the end faces of the first printed circuit board 1.1 substantially in the radial direction. A further rib 1.33 of the frame 1.3 extends over an angle of approximately 60° in a circular segment contour.

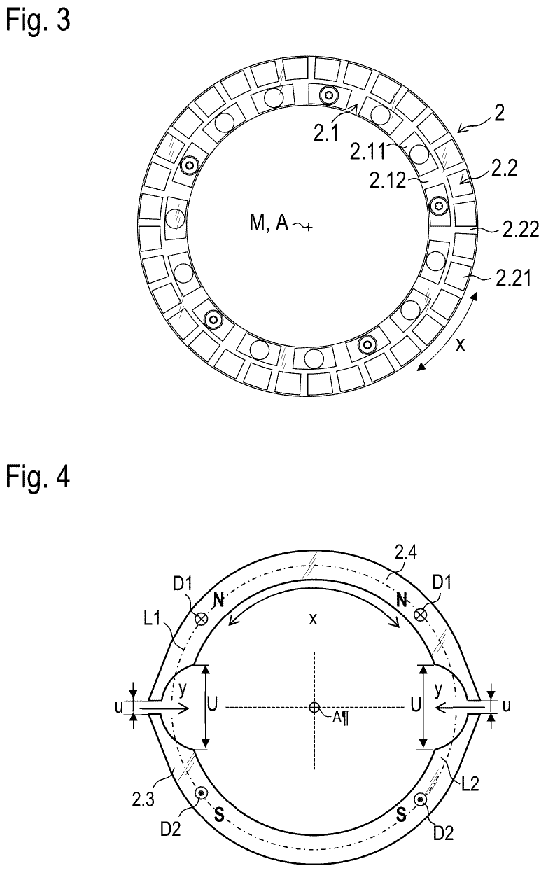

According to the embodiment example, the second component group 2 roughly has an annular form (see FIGS. 1 and 3). It comprises, on its end face, a first scale 2.1 and a second scale 2.2, the scales 2.1, 2.2 extending in a measurement direction x.

In this case, the scales 2.1, 2.2 are applied to a substrate 2.5, which is made of printed circuit board material in the embodiment example shown. The scales 2.1, 2.2 are annular and are arranged on the substrate 2.5, with different radii, concentrically in relation to the axis A.

According to FIG. 3, the scales 2.1, 2.2 comprise graduation structures, each consisting of a periodic sequence of electrically conductive graduation regions 2.11, 2.21 and non-conductive graduation regions 2.12, 2.22 arranged in alternation along the measurement direction x or circumferential direction, the electrically conductive graduation regions 2.11, 2.21 each being made of a layer of electrically conductive material. In the example shown, copper was applied to the substrate 2.5 as the material for the electrically conductive graduation regions 2.11, 2.21. In the non-conductive graduation regions 2.12, 2.22, however, the substrate 2.5 is not coated. By means of the arrangement having two scales 2.1, 2.2 in each case, the angular position of the second component group 2 can be determined in absolute terms. The outer, second scale 2.2 has the larger number of graduation regions 2.21, 2.22 along the circumferential direction x, and so these can obtain the higher resolution in terms of measuring the angular position.

In addition, a first magnet 2.3 and a second magnet 2.4 are arranged on the opposite side of the substrate 2.5 in relation to the scales 2.1, 2.2, the magnets 2.3, 2.4 being assigned to the second component group 2. The magnets 2.3 and 2.4 and the substrate 2.5 are thus each rigidly interconnected and move at the same rate or rotational speed as the scales 2.1, 2.2. The magnets 2.3, 2.4 are arranged end to end in the measurement direction x, which here corresponds to the circumferential direction, and each have a midline L1, L2 extending in the measurement direction x (see also FIG. 4).

In the embodiment example shown, the magnets 2.3, 2.4 are configured as plastics-bonded magnets. Accordingly, they comprise plastics material having a magnetizable filler or magnetic powder. The filler is embedded in a plastics matrix. In particular, the magnets 2.3, 2.4 can be configured as pressed magnets, the magnetizable filler being embedded in a thermosetting plastics matrix, e.g., epoxy resin. Alternatively, the magnets 2.3, 2.4 can also be produced in an injection molding method.

The magnets 2.3, 2.4 are arranged such that they have opposite magnetization directions D1, D2. In addition, the magnets 2.3, 2.4 are configured as permanent magnets and are each magnetized through their thickness, i.e., such that their magnetization directions D1, D2 are oriented axially here. The magnets 2.3, 2.4 have opposite magnetization directions D1, D2. In the embodiment example shown, the two magnets 2.3, 2.4 are identical, which is advantageous for assembly and stockkeeping.

The ends of the magnets 2.3, 2.4 are configured such as to taper. Accordingly, the first magnet 2.3 and the second magnet 2.4 are configured such that the distance u, U extending in the measurement direction x between the first magnet 2.3 and the second magnet 2.4 varies when said distance is ascertained at different points along a second direction y. In FIG. 4, the distance u, U increases along the second direction y following the arrow. The second direction y runs orthogonally to the measurement direction x, i.e., in this case radially with respect to the axis A or in the radial direction. Thus, the distance u, U varies in size along the second direction y or in accordance with a position along the second direction y. The contours of the mutually facing ends of the magnets 2.3, 2.4 are configured in mirror symmetry with respect to an axis of symmetry that is oriented in parallel with the second direction y. In addition, the ends of the magnets 2.3, 2.4 are configured such that their contours run asymmetrically with respect to a line that is oriented in parallel with the measurement direction x, in particular with respect to the midline L1, L2. In the region in which the distance u, U in the measurement direction x between the magnets 2.3, 2.4 varies, the first magnet 2.3 and the second magnet 2.4 or their contours are configured such that said distance u, U varies continuously along the second direction y, i.e., such that the contours there are configured as smooth curves and without any step changes along the second direction y.

To determine the angle information, according to FIG. 2 the first printed circuit board 1.1 has a first detector unit 1.11, a second detector unit 1.12, a third detector unit 1.13, and a fourth detector unit 1.14. The detector units 1.11 to 1.14 are each in the form of a ring segment; for each of the detector units 1.11 to 1.14, the midpoint M of the ring segment form is on the axis A. Accordingly, the detector units 1.11 to 1.14 are opposite one another roughly concentrically in relation to the midpoint M.

The first detector unit 1.11 comprises a first exciter trace 1.111 and first receiver conducting tracks 1.112. Likewise, the second detector unit 1.12 comprises a second exciter trace 1.121 and second receiver conducting tracks 1.122, the third detector unit 1.13 comprises a third exciter trace 1.131 and third receiver conducting tracks 1.132, and the fourth detector unit 1.14 comprises a fourth exciter trace 1.141 and fourth receiver conducting tracks 1.142.

The exciter traces 1.111, 1.121, 1.131, 1.141 each enclose associated receiver conducting tracks 1.112, 1.122, 1.132, 1.142. Both the exciter traces 1.111, 1.121, 1.131, 1.141 and the receiver conducting tracks 1.112, 1.122, 1.132, 1.142 extend along the measurement direction x.

In the embodiment example shown, each detector unit 1.11, 1.12, 1.13, 1.14 comprises four receiver conducting tracks 1.112, 1.122, 1.132, 1.142 arranged in a manner offset in the measurement direction x or circumferential direction such that they can deliver four phase-shifted signals in accordance with the offset. In the embodiment example shown, adjacent receiver conducting tracks 1.112, 1.122, 1.132, 1.142 are arranged inside a detector unit 1.11, 1.12, 1.13, 1.14 in a manner offset from one another by ⅛ of the full sine period (by p/4 or 45° along the circumferential direction x).

In FIG. 2, the receiver conducting tracks 1.112, 1.122, 1.132, 1.142 belonging to one and the same detector unit 1.11, 1.12, 1.13, 1.14 are denoted by just one reference numeral. In addition, the receiver conducting tracks 1.112, 1.122, 1.132, 1.142 of the detector units 1.11 to 1.14 run in different layers of the first printed circuit board 1.1 and are connected by vias, such that undesirable short circuits at intersection points are avoided. Although, strictly speaking, each of the receiver conducting tracks 1.112, 1.122, 1.132, 1.142 consists of many conductor pieces, each distributed and mounted end to end in two different planes or layers, a structure of this kind is hereinafter referred to collectively as a receiver conducting track 1.112, 1.122, 1.132, 1.142.

The receiver conducting tracks 1.112, 1.122, 1.132, 1.142 of a detector unit 1.11, 1.12, 1.13, 1.14 are electrically wired such that they deliver 0° and 90° signals as well as 45° and 135° signals. A first position signal can be determined from the 0° and 90° signals, and a second position signal, which is redundant in relation to the first position signal, can be determined from the 45° and 135° signals.

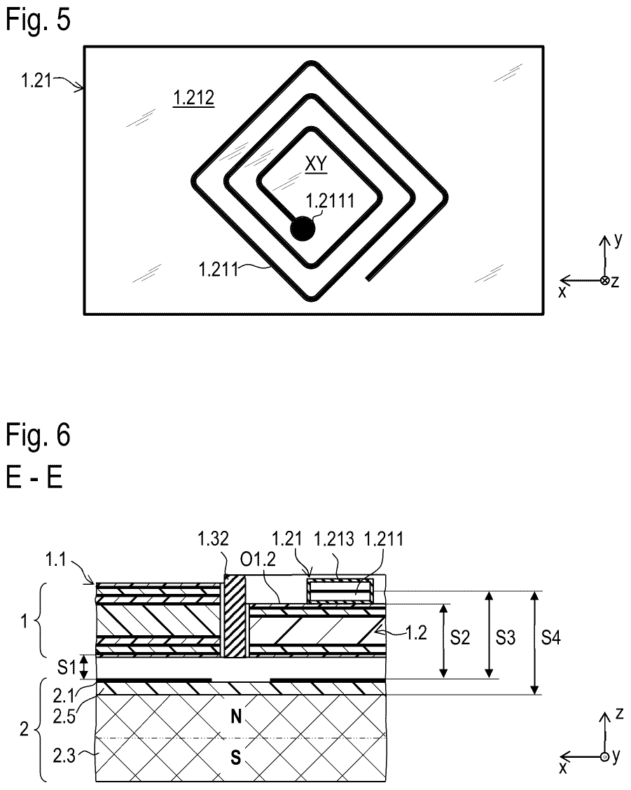

In addition, the first component group 1 comprises the second printed circuit board 1.2, which is configured in the manner of a ring segment and, in the embodiment example shown, extends over an angle of approximately 52°. The domain-wall memory 1.21 is mounted on the second printed circuit board 1.2. According to FIG. 5, the domain-wall memory 1.21 comprises a domain-wall conductor 1.211 and a substrate 1.212, the domain-wall conductor 1.211 being applied to the substrate 1.212 in the form of a conducting track and running in (or on) a first face XY. At one end, the domain-wall conductor 1.211 has a domain-wall generator 1.2111. In the embodiment example shown, the substrate 1.212 has a mechanically load-bearing silicon layer, the substrate 1.212 being configured in a planar manner and it being possible for the domain-wall conductor 1.211 to be part of a CMOS chip. Alternatively, the substrate can have a glass layer. The domain-wall conductor 1.211 comprises a magnetically soft material, for example a Ni—Fe alloy. The domain-wall conductor 1.211 can be configured as an open spiral, as shown in FIG. 5, or have a closed shape.

When the position measuring device is in operation, the first component group 1 and the second component group 2 are opposite each other. In the embodiment example shown, the first component group 1 can be operated as the stator and the second component group 2 as the rotor. The first printed circuit board 1.1 is used for reading the scales 2.1, 2.2. In the embodiment example shown, the electronic components are mounted only on one side of the first printed circuit board 1.1, namely on the side facing away from the scales 2.1, 2.2. The domain-wall memory 1.21 is used for ensuring a multi-turn functionality, i.e., for counting several revolutions or passes. The domain-wall memory 1.21 is arranged such that the face XY in which the domain-wall conductor 1.211 runs (or is arranged) is oriented orthogonally to the magnetization direction D1, D2.

FIG. 6 is a partial sectional view (E-E; see FIG. 2) through the first component group 1 and the second component group 2. Overall, the first printed circuit board 1.1 here has six electrically conductive layers. The first printed circuit board 1.1 can be separated into two halves by an imaginary plane extending in the x-y direction. The electrically conductive layers located in the half of the first printed circuit board 1.1 facing the scales 2.1, 2.2 (the bottom half in FIG. 6) are structured such as to form the detector units 1.11 to 1.14. By contrast, the other three electrically conductive layers, located in the top half of the first printed circuit board 1.1 in FIG. 6, are used for connecting the electronic components of the electrical circuit.

The second printed circuit board 1.2 can have a simpler construction and, in the embodiment example shown, has just four electrically conductive layers. These are used for connecting the electronic components of the electrical circuit, which is ultimately used for counting the revolutions or passes. The domain-wall memory 1.21 has a housing 1.213 which has electrical connection sites and in which the domain-wall conductor 1.211 together with the substrate 1.212 is arranged. The housing 1.213 is mounted on a first surface O1.2 of the second printed circuit board 1.2.

To ensure the second printed circuit board 1.2 can be accurately positioned in a simple manner during mounting of the first component group 1, the frame 1.3 and the second printed circuit board 1.2 have suitable guide surfaces.

Between the component groups 1, 2 there is an air gap extending in a third direction z. A first distance extends in the third direction z between the scale 2.1 and the closest layer of the first printed circuit board 1.1 to the scale 2.1, in which layer at least some parts of the detector unit 1.11, 1.12, 1.13, 1.14, in particular portions of the receiver conducting tracks 1.112, 1.122, 1.132, 1.142, are arranged. This first distance is of a length S1. A second distance extending between the scale 2.1 and the first surface O1.2 is of a second length S2. In this case, the first length S1 is less than the second length S2, thus satisfying the constraint S1≤S2. Moreover, a third distance extending between the domain-wall conductor 1.211 and the scale 2.1 is of a third length S3; in this case, the first length S1 is less than the third length S3, so here too the criterion S1≤S3 is satisfied.

In the assembled state, therefore, the detector units 1.11, 1.12, 1.13, 1.14 and the scales 2.1, 2.2 are opposite each other across an axial distance or gap, such that in the event of relative rotation between the first component group 1 and the second component group 2, a signal dependent on the particular angular position can be generated in each case in the receiver conducting tracks 1.112, 1.122, 1.132, 1.142 by induction effects. A pre-requisite for generating appropriate signals is that the exciter traces 1.111, 1.121, 1.131, 1.141 generate a periodically alternating electromagnetic excitation field in the region of each graduation structure that is read. In the embodiment example shown, the exciter traces 1.111, 1.121, 1.131, 1.141 are formed as a plurality of energized individual planar-parallel conducting tracks. The first printed circuit board 1.1 has an electronic circuit comprising the electrically interconnected electronic components. The electronic circuit can also comprise an ASIC module, for example. The signals generated by the receiver conducting tracks 1.112, 1.122, 1.132, 1.142 are processed further by means of some of the electronic components, which form an evaluation circuit. This electronic circuit of the reading element 1 works not only as an evaluation element but also as an exciter control element, under the control of which the excitation current is generated or produced, which then flows through the exciter traces 1.111, 1.121, 1.131, 1.141. Thus, current is applied to the exciter traces 1.111, 1.121, 1.131, 1.141 by one and the same exciter control element.

When current is applied to the exciter traces 1.111, 1.121, 1.131, 1.141, an electromagnetic field having a tube-like or cylindrical orientation thus forms around the exciter traces 1.111, 1.121, 1.131, 1.141. The field lines of the resulting electromagnetic field run around the exciter traces 1.111, 1.121, 1.131, 1.141, the direction of the field lines depending, as is known, on the direction of the current in the exciter traces 1.111, 1.121, 1.131, 1.141. Eddy currents are induced in the region of the electrically conductive graduation regions 2.11, 2.21 such that in each case a field modulation dependent on the angular position is obtained. Accordingly, the relative angular position can be measured in each case by the receiver conducting tracks 1.112, 1.122, 1.132, 1.142.

When a magnetic field moving relative to the domain-wall conductor 1.211 acts suitably on the domain-wall conductor 1.211, domain walls are displaced within or along the domain-wall conductor 1.211. To create an optimized magnetic field, a magnet arrangement as described above is used, comprising the magnets 2.3, 2.4 that have tapers at each of the mutually facing ends of the magnets 2.3, 2.4. It has proven extremely advantageous if, as in the embodiment example, the contour of each end of a magnet 2.3, 2.4 runs in a curved manner such that the magnets 2.3, 2.4 have a concave portion at each of their ends. To even out the magnetic field in the region of the transition from the first magnet 2.3 to the second magnet 2.4, the minimum distance u is in this case selected to be greater than zero. The size of the minimum distance u between the first and the second magnet 2.3, 2.4 is also such as to be less than half the length S4 of the fourth distance between the domain-wall conductor 1.211 and the magnets 2.3, 2.4 (u<½ S4).

In relation to the second direction y, the domain-wall conductor 1.211 is positioned such that the magnets 2.3, 2.4 pass by it in the region of the smallest distance u. If the magnets 2.3, 2.4 now move relative to the domain-wall conductor 1.211 in the measurement direction x, a magnetic field that is rotating, so to speak, in the plane of the domain-wall conductor 1.211, i.e., in the face XY, acts on the domain-wall conductor 1.211 at the ends and in particular in the region of the gap between the magnets 2.3, 2.4. As a result, the positions of domain walls are displaced, the displacement field being generated by the magnets 2.3, 2.4 being guided past the domain-wall conductor 1.211.

After each time the ends of the magnets 2.3, 2.4 travel past the domain-wall conductor 1.211, or after each half-revolution of the second component group 2, the domain wall or walls move further.

The magnetization directions within portions of the domain-wall conductor 1.211, and thus the positions of the domain walls, can be detected by the readout elements integrated in the domain-wall memory 1.21. In this way, in an angular-position measuring device, revolutions can be counted or the revolution information stored even when no auxiliary power can be used. By way of example, this is important if a shaft is moved, for example under a weight load, during a power outage. Moreover, the domain walls are displaced in a manner dependent on the direction of rotation such that the domain-wall memory 1.21 can be used reliably in applications that allow for both directions of rotation.

The reading of the scales 2.1, 2.2 by the detector units 1.11, 1.12, 1.13, 1.14 yields a relatively accurate determination of the angular position within one revolution. For the absolute determination of the angular position over a plurality of revolutions, the angular position (fine position) ascertained by the reading device 1.12 has to be synchronized with the revolution information (rough position) of the domain-wall conductor 1.211.

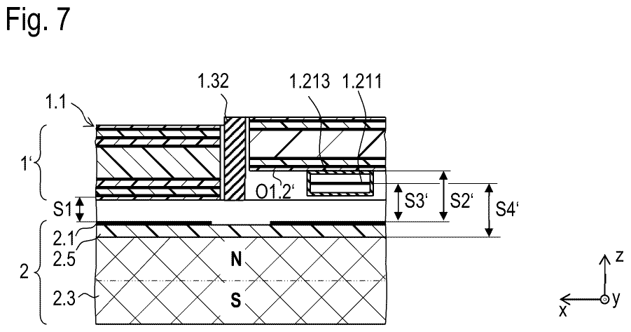

FIG. 7 shows a second embodiment example. It differs from the first embodiment example substantially in that the first surface O1.2′ of the second printed circuit board 1.2 is now arranged facing the scales 2.1, 2.2.

The housing 1.213 is mounted on the first surface O1.2′ of the second printed circuit board 1.2. Accordingly, the first distance is still of the length S1 in the second embodiment example. By contrast, the second distance extending between the scale 2.1 and the first surface O1.2′ is of the second length S2′, which in this case is shorter than the second length S2 according to the first embodiment example. However, in the second embodiment example too, the first length S1 is less than the second length S2′, thus satisfying the criterion (S1≤S2′). Moreover, the third distance extending between the domain-wall conductor 1.211 and the scale 2.1 is of the third length S3′. In the second embodiment example too, the first length S1 is less than the third length S3′; the general rule is that S1≤S3′.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. A position measuring device comprising:
a first component group; and
a second component group,
wherein the component groups are arranged so as to be movable relative to one another in a measurement direction,
wherein the first component group comprises:
a first printed circuit board comprising a detector, and
a second printed circuit board comprising a domain-wall conductor,
wherein the first printed circuit board is arranged offset from the second printed circuit board in the measurement direction,
wherein the second component group comprises:
a scale, and
a magnet,
wherein the scale is arranged between the magnet and the second printed circuit board,
wherein the scale is configured to be read by the detector to determine a relative position in the measurement direction, and
wherein the magnet is configured and arranged such that the magnet generates a displacement of a domain wall in the domain-wall conductor when the magnet travels past domain-wall conductor.

2. The position measuring device according to claim 1, wherein the domain-wall conductor is arranged in a housing mounted on a first surface of the second printed circuit board,
wherein a first distance between the scale and the detector is of a first length,
wherein a second distance between the first surface and the scale is of a second length, and
wherein the first length is less than or equal to the second length.

3. The position measuring device according to claim 1,
wherein a first distance between the scale and the detector is of a first length,
wherein a third distance between the domain-wall conductor and the scale is of a third length, and
wherein the first length is less than or equal to the third length.

4. The position measuring device according to claim 1, wherein the first printed circuit board and the second printed circuit board are each configured in multiple layers, and wherein a layered construction of the first printed circuit board differs from a layered construction of the second printed circuit board.

5. The position measuring device according to claim 1, wherein the position measuring device is configured for inductive measurement, and wherein the detector has at least one receiver conducting track.

6. The position measuring device according to claim 1, wherein the position measuring device is configured as an angular-position measuring device.

7. The position measuring device according to claim 6, wherein the first printed circuit board is configured in a manner of a ring segment and extends over an angle of at least 180°.

8. The position measuring device according to claim 6, wherein the second printed circuit board is configured in a manner of a ring segment and extends over an angle of less than 180°.

9. The position measuring device according to claim 1, wherein a material of the magnet comprises plastics material having a magnetizable filler.

10. The position measuring device according to claim 1, wherein the first and second component groups are arranged so as to be rotatable relative to one another about an axis, and wherein a face in which the domain-wall conductor runs is not intersected by the axis.

11. The position measuring device according to claim 1, wherein the second component group comprises two magnets.

12. The position measuring device according to claim 11, wherein the two magnets are:
arranged end to end in the measurement direction,
magnetized such that their magnetization directions run with an orthogonal directional component with respect to the face, and
arranged such that each of the two magnets have opposite magnetization directions, and
wherein the two magnets are arranged and configured such that a distance in the measurement direction between a first magnet of the two magnets and a second magnet of the two magnets varies in size along a second direction that is oriented orthogonally to the measurement direction.

13. The position measuring device according to claim 11, wherein the two magnets are arranged end to end in the measurement direction such that they do not touch.

14. The position measuring device according to claim 11, wherein a fourth distance extending orthogonally to a face in which the domain-wall conductor runs is located between the domain-wall conductor and the two magnets,
wherein the fourth distance is of a fourth length, and
wherein a minimum distance in the measurement direction between the two magnets is less than half the fourth length.
